(19) United States
(12) Patent Application Publication
(10) Pub. No.: US 2026/0371876 A1
(43) Pub. Date: Nov. 19, 2026

(54) DISPLAY DEVICE AND DISPLAY PANEL

(71) Applicant: LG DISPLAY CO., LTD., Seoul (KR)

(72) Inventors: Chaiwon KIM, Paju-si (KR); SeungHwan SHIN, Paju-si (KR); Dongmin LIM, Paju-si (KR); WonHo LEE, Paju-si (KR)

(21) Appl. No.: 19/642,599

(22) Filed: Apr. 8, 2026

(30) Foreign Application Priority Data
May 19, 2025 (KR) 10-2025-0064362

(51) Int. Cl. H10K 59/131; G09G 3/20; G09G 3/3233; G09G 3/3275; G09G 3/36

(52) U.S. Cl. CPC H10K 59/131; G09G 3/2096; G09G 3/3233; G09G 3/3275; G09G 3/3688; G09G 2300/0426; G09G 2300/0452; G09G 2300/0842; G09G 2310/08

(57) ABSTRACT

A display panel includes a pixel group in a 3 x 2 arrangement in which three pixels are arranged in a first direction and two pixels are arranged in a second direction; three gate lines extending along the first direction and supplying gate signals; a first pixel data line extending along the second direction and supplying a first pixel data voltage to a first pixel sub-group; and a second pixel data line extending along the second direction and supplying a second pixel data voltage to a second pixel sub-group.

### CROSS REFERENCE TO RELATED APPLICATION

This application claims priority from and the benefit of Korean Patent Application No. 10-2025-0064362, filed on May 19, 2025, which is hereby incorporated by reference for all purposes as if fully set forth herein.

### BACKGROUND

### FIELD

Embodiments of the invention relate generally to a display device and a display panel.

### DISCUSSION OF THE BACKGROUND

As the information society develops, the demands for display devices for displaying images have increased, and various types of display devices, such as liquid crystal displays and organic light-emitting displays, are widely used.

Among these display devices, an organic light-emitting display device uses organic light emitting diodes that emit light themselves and thus provides advantages such as fast response speed, high contrast ratio, high luminous efficiency, high luminance, and a wide viewing angle.

A display device typically includes a light-emitting element disposed in each of a plurality of subpixels arranged on a display panel. The display device controls the luminance of each subpixel by controlling a voltage supplied to the light-emitting element, thereby displaying an image.

Various studies have been conducted to improve the performance of such display devices, including increasing size, reducing thickness and weight, increasing resolution, and reducing power consumption.

Recently, to reduce circuit costs of display devices, a Double Rate Driving (DRD) method has been developed. This method reduces the number of data driving circuits by reducing the number of data lines by half while doubling the number of gate lines compared with conventional methods.

However, because the number of gate lines is doubled in the Double Rate Driving (DRD) method, one horizontal period of a scan signal supplied through a gate line may be shortened, which makes it difficult to secure sufficient charging time for a data voltage.

The above information disclosed in this Background section is only for understanding of the background of the inventive concepts, and, therefore, it may contain information that does not constitute prior art.

### SUMMARY

Embodiments of the invention provide a display device and a display panel having an improved structure capable of securing a charging time for a data voltage while reducing the number of data lines.

Embodiments of the invention provide a display device and a display panel having an improved structure capable of controlling one pixel group with three gate lines and two pixel data lines by setting 3 x 2 pixels as one pixel group.

Embodiments of the invention provide a display device and a display panel having an improved structure capable of securing a charging time for a data voltage by arranging one gate line for each pixel line in a first direction, while arranging two pixel data lines for every three pixel lines in a second direction.

Embodiments of the invention provide a display device and a display panel having an improved structure capable of reducing noise capacitance due to line overlap by connecting a pixel located at the center of a pixel group with a data bridge line extending from pixel data lines on both sides.

Additional features of the inventive concepts will be set forth in the description which follows, and in part will be apparent from the description, or may be learned by practice of the inventive concepts.

According to an embodiment, a display panel includes a plurality of pixel groups, each of which having a 3 x 2 arrangement in which three pixels are arranged in a first direction and two pixels are arranged in a second direction; a gate driving circuit configured to supply a gate signal to the display panel through a gate line; and a data driving circuit configured to supply a pixel data voltage to the display panel through a pixel data line. The pixel group may include a first pixel sub-group to which a first pixel data voltage is supplied through a first pixel data line extending along the second direction; and a second pixel sub-group to which a second pixel data voltage is supplied through a second pixel data line extending along the second direction. The pixel group may operate based on three gate signals supplied through three gate lines extending along the first direction.

The first pixel sub-group may be arranged in a shape similar to the second pixel sub-group.

The first pixel sub-group may include an 11th pixel of a first row and a first column; a 12th pixel of the first row and a second column; and a 21st pixel of a second row and the first column.

The second pixel sub-group may include a 13th pixel of the first row and a third column; a 22nd pixel of the second row and the second column; and a 23rd pixel of the second row and the third column.

The three gate lines may include a first gate line disposed outside the pixels of the first row; a second gate line disposed between the pixels of the first row and the pixels of the second row; and a third gate line disposed outside the pixels of the second row.

The 11th pixel and the 13th pixel may operate by a first gate signal supplied through the first gate line, the 12th pixel and the 23rd pixel may operate by a second gate signal supplied through the second gate line, and the 21st pixel and the 22nd pixel may operate by a third gate signal supplied through the third gate line.

The 11th pixel and the 21st pixel may be supplied with the first pixel data voltage through the first pixel data line, the 13th pixel and the 23rd pixel may be supplied with the second pixel data voltage through the second pixel data line, the 12th pixel may be supplied with the first pixel data voltage through a first data bridge line branching from the first pixel data line, and the 22nd pixel may be supplied with the second pixel data voltage through a second data bridge line branching from the second pixel data line.

The first data bridge line may branch at a first data line contact point formed adjacent to an emission area of the 11th pixel, and the second data bridge line may branch at a second data line contact point formed adjacent to an emission area of the 23rd pixel.

The data bridge line may be formed of a material constituting an active layer of the driving transistor, and may be electrically connected through the lower light shield layer at the first data line contact point or the second data line contact point.

Each pixel in the pixel group may include an emission area and a circuit area, and pixels in the pixel group may be arranged such that the circuit areas do not overlap along the first direction.

The 12th pixel and the 22nd pixel may be arranged such that respective circuit areas are adjacent to each other in the second direction.

The display device may further include a driving voltage line extending along the second direction in a space between adjacent pixels in the first direction and transmitting a pixel high-potential voltage; and a driving voltage bridge line branching from the driving voltage line in the first direction along a space between the circuit area of the 12th pixel and the circuit area of the 22nd pixel.

Each pixel in the pixel group may include an emission area and a circuit area, and the pixel group may have a flip structure in which the arrangement of the emission area and the circuit area alternates in units of pixels.

Each of the first pixel data line and the second pixel data line may include a plurality of subpixel data lines extending in the second direction along spaces between a part of adjacent sub-pixels in the pixels of the pixel groups, and the first data line contact point and the second data line contact point may be respectively located at positions adjacent to emission area of each subpixel in the spaces.

According to another embodiment, a display panel includes a pixel group of a 3 x 2 arrangement in which three pixels are arranged in a first direction and two pixels are arranged in a second direction; three gate lines extending along the first direction and supplying gate signals; a first pixel data line extending along the second direction and supplying a first pixel data voltage to a first pixel sub-group; and a second pixel data line extending along the second direction and supplying a second pixel data voltage to a second pixel sub-group.

The three gate lines may include a first gate line disposed outside pixels of a first row; a second gate line disposed between the pixels of the first row and pixels of a second row; and a third gate line disposed outside the pixels of the second row.

One of the pixels disposed in a center column in the pixel group may be supplied with the first pixel data voltage through a first data bridge line branching from the first pixel data line, and the other of the pixels disposed in the center column in the pixel group may be supplied with the second pixel data voltage through a second data bridge line branching from the second pixel data line.

The first data bridge line may branch at a first data line contact point formed adjacent to an emission area of a pixel located in a left column in the pixel group, and the second data bridge line may branch at a second data line contact point formed adjacent to an emission area of a pixel located in a right column in the pixel group.

The data bridge line may be formed of a material constituting an active layer of a driving transistor, and may be electrically connected through a lower light shield layer at the first data line contact point or the second data line contact point.

Each pixel in the pixel group may include an emission area and a circuit area, and the pixel group may have a flip structure in which the arrangement of the emission area and the circuit area alternates in units of pixel.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic diagram illustrating a display device according to an embodiment of the invention.

FIG. 2 is a diagram illustrating a display device according to an embodiment of the invention.

FIG. 3 is a subpixel circuit diagram illustrating a display device according to an embodiment of the invention.

FIG. 4 is a cross-sectional view illustrating a display panel in a display device according to an embodiment of the invention.

FIG. 5 is a subpixel arrangement diagram illustrating a double rate driving structure in a display device according to an embodiment of the invention.

FIG. 6 is a diagram illustrating a connection relationship between gate lines and data lines for each pixel group in a display device according to an embodiment of the invention.

FIG. 7 is a diagram illustrating a signal timing for gate signals and data voltages of a display device according to an embodiment of the invention.

FIG. 8 is a diagram illustrating a pixel group structure of a display device according to an embodiment of the invention.

FIG. 9 is an enlarged view of area A1 of FIG. 8.

FIG. 10 is an enlarged view of area A2 of FIG. 8.

FIG. 11 is a cross-sectional view taken along the X-Y direction at the data line contact point of FIG. 10.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

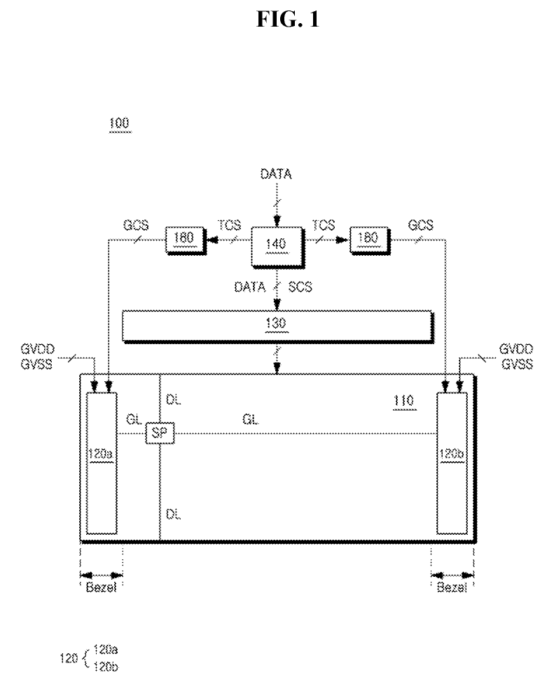

FIG. 1 is a schematic diagram illustrating a display device according to an embodiment of the invention.

Referring to FIG. 1, a display device 100 according to an embodiment of the invention includes a display panel 110, a gate driving circuit 120, a data driving circuit 130, a timing controller 140, and a level shifter 180.

A plurality of data lines DL and a plurality of gate lines GL cross each other on the display panel 110, and subpixels SP may be arranged in a matrix form at each intersection area to configure a subpixel array.

In the case of a liquid crystal display device, the display panel 110 includes a liquid crystal layer formed between two substrates, and may be operated in a mode such as a Twisted Nematic (TN) mode, a Vertical Alignment (VA) mode, an In Plane Switching (IPS) mode, or a Fringe Field Switching (FFS) mode. In the case of an organic light emitting display device, the display panel 110 may be implemented as a top emission type, a bottom emission type, or a dual emission type.

One subpixel SP may include a thin film transistor (TFT) disposed in an area formed by one data line DL and one gate line GL, a light emitting element that emits light according to a data voltage, and a storage capacitor electrically connected to the light emitting element to maintain a voltage. The thin film transistor may include a driving transistor and one or more switching transistors, and may be implemented as a P-type transistor or an N-type transistor. Alternatively, the thin film transistor may be implemented in a hybrid form in which a P-type transistor and an N-type transistor are mixed.

For example, if the display device 100 having a resolution of 2,160 x 3,840 is composed of four subpixels SP of white (W), red (R), green (G), and blue (B), there may be 2,160 gate lines GL and a total of 15,360 data lines DL (3,840 x 4 = 15,360), in which four data lines DL are respectively electrically connected to the four subpixels WRGB for each column, and the subpixels SP may be disposed in areas formed by the gate lines GL and data lines DL, respectively.

The timing controller 140 may receive image data DATA from an external host system (not shown) through various interface methods. The timing controller 140 may correct the image data DATA so that a driving deviation of the subpixels SP is compensated based on a sensing result for a characteristic value of the subpixel (e.g., a threshold voltage or mobility of the driving transistor), and then transmit the corrected image data to the data driving circuit 130.

The timing controller 140 may receive timing signals such as a vertical synchronization signal, a horizontal synchronization signal, and a data enable signal from the host system. The timing controller 140 generates a source control signal SCS for controlling the operation timing of the data driving circuit 130 and a timing control signal TCS for controlling the operation timing of the gate driving circuit 120 based on the timing signals input from the host system.

The source control signal SCS may include a source sampling clock, a source output enable signal, or the like. The source sampling clock is a clock that controls sampling timing of the image data DATA in the data driving circuit 130 based on a rising or falling edge. The source output enable signal is a signal that controls output timing for an analog data voltage supplied to the display panel 110.

The data driving circuit 130 may include a plurality of source driving integrated chips SDIC. The data driving circuit 130 may receive the image data DATA from the timing controller 140. The data driving circuit 130 may convert the image data DATA into a gamma compensation voltage in response to the source control signal SCS transmitted from the timing controller 140 to generate a data voltage, and supply the data voltage to the data lines DL of the display panel 110 in synchronization with a scan signal of the gate driving circuit 120.

The data driving circuit 130 may be connected to the data lines DL of the display panel 110 by a Chip-On-Glass (COG) process or a Tape Automated Bonding (TAB) process, without being limited thereto.

The display device 100 may include the level shifter 180 that generates a gate control signal GCS using the timing control signal TCS output from the timing controller 140 and supply the gate control signal GCS to the gate driving circuit 120. The level shifter 180 may be disposed inside the gate driving circuit 120 or may be disposed on a source printed circuit board where the data driving circuit 130 is disposed.

The level shifter 180 may convert a transistor-transistor-logic (TTL) level voltage of the timing control signal TCS input from the timing controller 140 into a turn-on level voltage and a turn-off level voltage capable of switching transistors formed on the display panel 110. Then, the level shifter 180 may supply the gate control signal GCS to the gate driving circuit 120.

The timing control signal TCS may include an on-clock, an off-clock, a gate start pulse, and an alternating control pulse.

The gate control signal GCS may include an output start pulse, a gate clock, an even alternating voltage, an odd alternating voltage, a line selection signal, a reset signal, and a panel-on signal. The gate clock may be composed of N-phase clocks (N is a natural number) having different phases.

For example, in the display device 100 having a resolution of 2,160 x 3,840, a case where scan signals are sequentially output from a first gate line to a 2,160th gate line for the 2,160 gate lines GL may be referred to as 2,160-phase driving. Alternatively, a case where scan signals are sequentially output in units of four gate lines GL, such as sequentially outputting scan signals from the first gate line to a fourth gate line and then sequentially outputting scan signals from a fifth gate line to an eighth gate line, may be referred to as 4-phase driving. More particularly, a case where scan signals are sequentially output for every N gate lines GL may be referred to as N-phase driving.

In this case, the gate driving circuit 120 may include one or more gate driving integrated circuits GDIC.

The gate driving circuit 120 may output a display scan signal during a display driving period and output a sensing scan signal for sensing a characteristic value of the subpixel SP during a blank period, based on the gate control signal GCS input from the level shifter 180 and one or more power voltages GVDD and GVSS input from a power management circuit (not shown).

The gate driving circuit 120 may be directly formed on the substrate of the display panel 110 in a Gate-In-Panel (GIP) manner, but is not limited thereto.

The gate driving circuit 120 may be formed in a bezel area where an image is not displayed on the display panel 110, but is not limited thereto. The gate driving circuit 120 may be formed in a double bank structure in which a first gate driving circuit 120a is disposed in a first bezel area of the display panel 110 and a second gate driving circuit 120b is disposed in a second bezel area of the display panel 110 in order to minimize distortion of the scan signal due to signal delay.

The timing controller 140 controls a display driving operation and a sensing driving operation for subpixel lines of the display panel 110 based on the source control signal SCS and the timing control signal TCS, thereby sensing characteristic values for the subpixels SP in real time even in a section displaying an image.

Here, the subpixel line refers to a set of subpixels SP of one line arranged in a horizontal direction or a vertical direction. In addition, if three or four subpixels SP of different colors constitute one pixel, a set of pixels of one line arranged in a horizontal direction or a vertical direction may be referred to as a pixel line.

The sensing driving operation refers to an operation of applying sensing data to subpixels SP disposed in a specific subpixel line to sense a characteristic value of a corresponding subpixel SP, and updating a compensation value for compensating for a change in the characteristic value of the corresponding subpixel SP based on a sensing result.

The display device 100 may include a power management circuit that supplies various voltages or currents to the display panel 110, the gate driving circuit 120, the data driving circuit 130, or the like, or controls various voltages or currents to be supplied.

The power management circuit may adjust a direct current voltage supplied from an external host system to generate power required for driving the display panel 110, the gate driving circuit 120, and the data driving circuit 130.

The display device 100 may be formed as various types of devices such as a liquid crystal display (LCD), an organic light emitting display (OLED), and a plasma display panel (PDP), without being limited thereto.

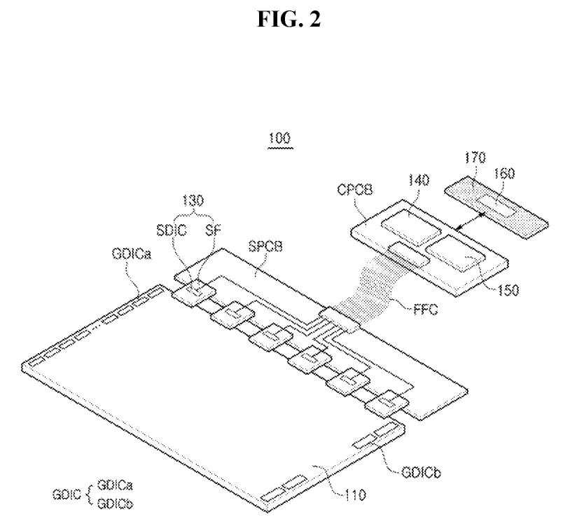

FIG. 2 is a system example diagram of a display device according to an embodiment of the invention.

FIG. 2 illustrates a case in which the data driving circuit 130 is implemented in a chip-on-film (COF) manner among various methods (TAB, COG, COF, etc.), and the gate driving circuit 120 is implemented in a gate-in-panel (GIP) form among various methods (TAB, COG, COF, GIP, etc.) in the display device 100 according to an embodiment of the invention.

If the gate driving circuit 120 is implemented in the Gate-In-Panel (GIP) form, a plurality of gate driving integrated circuits GDICa and GDICb included in the gate driving circuit 120 may be directly formed in the bezel area of the display panel 110. In this case, the gate driving integrated circuits GDICa and GDICb may receive various signals (gate clock, gate high signal, gate low signal, etc.) required for generating a scan signal through signal lines related to gate driving disposed in the bezel area.

Similarly, one or more source driving integrated circuits SDIC included in the data driving circuit 130 may be mounted on a source film SF, respectively, and one side of the source film SF may be electrically connected to the display panel 110. In addition, signal lines for electrically connecting the source driving integrated circuit SDIC and the display panel 110 may be disposed on the source film SF.

The display device 100 may include at least one source printed circuit board SPCB and a control printed circuit board CPCB for mounting control components and various electric devices for circuit connection between the plurality of source driving integrated circuits SDIC and other devices.

In this case, the other side of the source film SF on which the source driving integrated circuit SDIC is mounted may be connected to the at least one source printed circuit board SPCB. More particularly, one side of the source film SF on which the source driving integrated circuit SDIC is mounted may be electrically connected to the display panel 110, and the other side thereof may be electrically connected to the source printed circuit board SPCB.

The timing controller 140 and the power management circuit 150 may be mounted on the control printed circuit board CPCB. The timing controller 140 may control the operations of the data driving circuit 130 and the gate driving circuit 120. The power management circuit 150 may supply a driving voltage or current to the display panel 110, the data driving circuit 130, and the gate driving circuit 120, or may control the supplied voltage or current.

In addition, a memory (not shown) capable of storing the image data DATA input from the host system may be disposed on the control printed circuit board CPCB.

The at least one source printed circuit board SPCB and the control printed circuit board CPCB may be circuit-connected through at least one connecting member, and the connecting member may be formed of, for example, a flexible printed circuit (FPC), a flexible flat cable (FFC), or the like. In addition, the at least one source printed circuit board SPCB and the control printed circuit board CPCB may be integrated into one printed circuit board.

The display device 100 may further include a set board 170 electrically connected to the control printed circuit board CPCB. In this case, the set board 170 may be referred to as a power board. A main power management circuit 160 managing the entire power of the display device 100 may be disposed on such a set board 170. The main power management circuit 160 may interwork with the power management circuit 150.

In the case of the display device 100 configured as described above, a driving voltage is generated in the set board 170 and transmitted to the power management circuit 150 in the control printed circuit board CPCB. The power management circuit 150 transmits a driving voltage required for display driving or characteristic value sensing to the source printed circuit board SPCB through the flexible printed circuit FPC or the flexible flat cable FFC. The driving voltage transmitted to the source printed circuit board SPCB may be supplied to emit light or sense a specific subpixel SP in the display panel 110 through the source driving integrated circuit SDIC.

In this case, each subpixel SP arranged in the display panel 110 in the display device 100 may be composed of circuit elements such as a light emitting element and a driving transistor for driving the same.

The type and number of circuit elements constituting each subpixel SP may be variously determined according to provided functions and design methods.

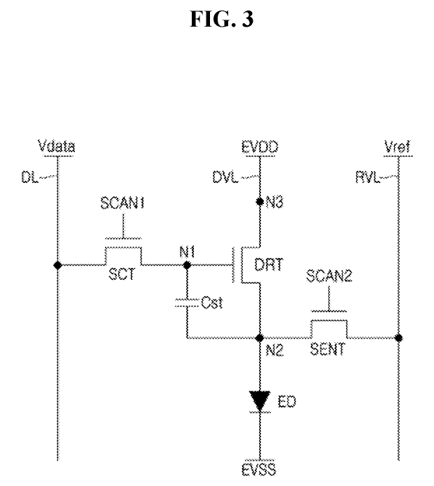

FIG. 3 illustrates an example of a subpixel circuit of a display device according to an embodiment of the invention.

Referring to FIG. 3, the subpixel circuit of the display device 100 according to an embodiment of the invention may include one or more transistors and a capacitor, and a light emitting element may be disposed therein.

For example, the subpixel circuit may include a driving transistor DRT, a scan transistor SCT, a sensing transistor SENT, a storage capacitor Cst, and a light emitting element ED.

The driving transistor DRT has a first node N1, a second node N2, and a third node N3. The first node N1 of the driving transistor DRT may be a gate node to which the data voltage Vdata is supplied from the data driving circuit 130 through the data line DL when the scan transistor SCT is turned on.

The second node N2 of the driving transistor DRT may be electrically connected to an anode electrode of the light emitting element ED, and may be a source node or a drain node.

The third node N3 of the driving transistor DRT is electrically connected to a driving voltage line DVL to which a pixel high-potential voltage EVDD is supplied, and may be a drain node or a source node.

In this case, the pixel high-potential voltage EVDD required for displaying an image may be supplied to the driving voltage line DVL during a display driving period. For example, the pixel high-potential voltage EVDD required for displaying an image may be 27V.

The scan transistor SCT is electrically connected between the first node N1 of the driving transistor DRT and the data line DL, and operates according to a first scan signal SCAN1 supplied through the gate line GL, with a gate node thereof electrically connected to the gate line GL. In addition, if the scan transistor SCT is turned on, the scan transistor transfers the data voltage Vdata supplied through the data line DL to the gate node of the driving transistor DRT, thereby controlling the operation of the driving transistor DRT.

The sensing transistor SENT is electrically connected between the second node N2 of the driving transistor DRT and a reference voltage line RVL, and operates according to a second scan signal SCAN2 supplied through the gate line GL. If the sensing transistor SENT is turned on, a reference voltage Vref supplied through the reference voltage line RVL is transferred to the second node N2 of the driving transistor DRT.

More particularly, the voltage of the first node N1 and the voltage of the second node N2 of the driving transistor DRT may be controlled by controlling the scan transistor SCT and the sensing transistor SENT, thereby allowing current for driving the light emitting element ED to be supplied.

The gate nodes of the scan transistor SCT and the sensing transistor SENT may be electrically connected together to one gate line GL, or may be electrically connected to different gate lines GL. Here, a structure in which the scan transistor SCT and the sensing transistor SENT are electrically connected to different gate lines GL is illustrated as an example. In this case, the scan transistor SCT and the sensing transistor SENT may be independently controlled by the first scan signal SCAN1 and the second scan signal SCAN2 transmitted through different gate lines GL.

Meanwhile, if the scan transistor SCT and the sensing transistor SENT are electrically connected to one gate line GL, the scan transistor SCT and the sensing transistor SENT may be simultaneously controlled by the first scan signal SCAN1 or the second scan signal SCAN2 transmitted through one gate line GL, thereby increasing the aperture ratio of the subpixel SP.

The first scan signal SCAN1 and the second scan signal SCAN2 supplied to the same subpixel may be collectively referred to as a gate signal.

Meanwhile, the transistors disposed in the subpixel circuit may be formed of P-type transistors as well as N-type transistors. Here, a case composed of N-type transistors is illustrated as an example.

The storage capacitor Cst is electrically connected between the first node N1 and the second node N2 of the driving transistor DRT, and maintains the data voltage Vdata for one frame.

The storage capacitor Cst may be electrically connected between the first node N1 and the third node N3 of the driving transistor DRT according to the type of the driving transistor DRT. The anode electrode of the light emitting element ED may be electrically connected to the second node N2 of the driving transistor DRT, and a pixel low-potential voltage EVSS may be supplied to a cathode electrode of the light emitting element ED.

Here, the pixel low-potential voltage EVSS may be a ground voltage or a voltage higher or lower than the ground voltage. In addition, the pixel low-potential voltage EVSS may vary according to a driving state. For example, the pixel low-potential voltage EVSS at a display driving period and the pixel low-potential voltage EVSS at a sensing driving period may be set differently. The pixel low-potential voltage EVSS may also be referred to as a base voltage.

The scan transistor SCT and the sensing transistor SENT may be referred to as switching transistors controlled through the scan signals SCAN1 and SCAN2.

In this case, in order to effectively sense a characteristic value of the driving transistor DRT, for example, a threshold voltage or mobility, the display device 100 may use a method of measuring the current flowing due to a voltage charged in the storage capacitor Cst in a characteristic value sensing period of the driving transistor DRT, which may be referred to as current sensing.

More particularly, the characteristic value or a change in the characteristic value of the driving transistor DRT in the subpixel SP may be measured by measuring the current flowing due to the voltage charged in the storage capacitor Cst in the characteristic value sensing period of the driving transistor DRT.

In this case, since the reference voltage line RVL serves not only to transfer the reference voltage Vref but also as a sensing line for sensing the characteristic value of the driving transistor DRT in the subpixel, the reference voltage line RVL may also be referred to as a sensing line or a sensing channel.

As described above, a subpixel circuit composed of three transistors DRT, SCT, and SENT and one capacitor Cst may be referred to as a 3T1C structure. However, the configuration of the subpixel circuit may be variously changed in other embodiments. For example, a subpixel circuit composed of two transistors DRT and SCT and one capacitor Cst without the sensing transistor SENT may be referred to as a 2T1C structure, and a subpixel circuit may be configured to further include one or more transistors and one or more capacitors.

In this case, the display device 100 may be arranged in a double rate driving (DRD) structure in which two (or a pair of) subpixels share one data line DL in order to reduce the number of data lines DL through which the data voltage Vdata is transmitted.

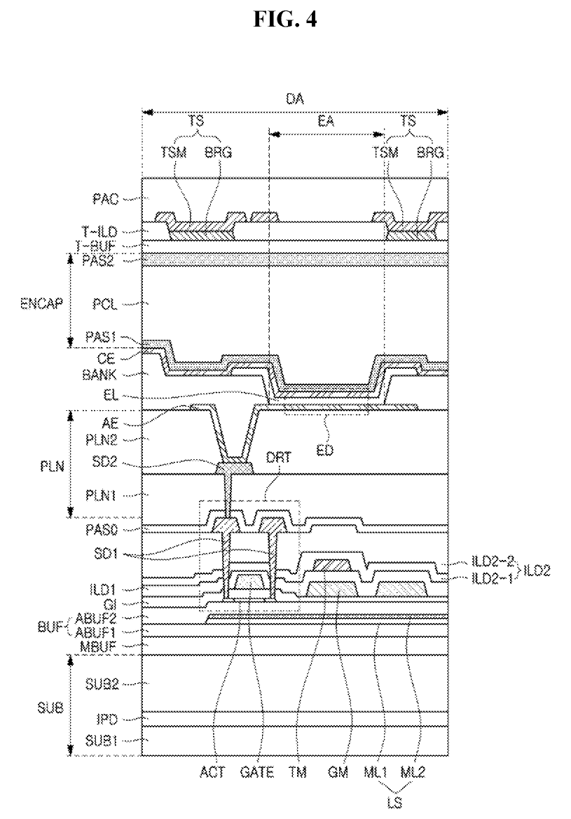

FIG. 4 illustrates an example of a cross-section of a display panel in a display device according to an embodiment of the invention.

Referring to FIG. 4, in the display device 100 according to an embodiment of the invention, the display panel 110 may include a substrate SUB, a driving transistor DRT, a planarization layer PLN, a light emitting element ED, an encapsulation layer ENCAP, and a touch layer.

Here, a display area DA where an image is displayed through the subpixel SP is illustrated as an example.

The substrate SUB may include a first substrate SUB1, an inter-substrate insulating film IPD, and a second substrate SUB2. The inter-substrate insulating film IPD may be disposed between the first substrate SUB1 and the second substrate SUB2.

By configuring the substrate SUB with the first substrate SUB1, the inter-substrate insulating film IPD, and the second substrate SUB2, moisture permeation may be prevented.

For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Various patterns ACT, SD1, and GATE for forming transistors such as the driving transistor DRT, various insulating films MBUF, ABUF1, ABUF2, GI, ILD1, ILD2, and PAS0, and various metal patterns TM, GM, ML1, and ML2 may be disposed on the substrate SUB.

A multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. Here, the first metal layer ML1 and the second metal layer ML2 may be a light shield layer LS that blocks light.

A second active buffer layer ABUF2 may be disposed on the first metal layer ML1 and the second metal layer ML2. An active layer ACT of the driving transistor DRT may be disposed on the second active buffer layer ABUF2.

A gate insulating film GI may be disposed while at least partially covering the active layer ACT.

A gate electrode GATE of the driving transistor DRT may be disposed on the gate insulating film GI. In this case, a gate material layer GM may be disposed on the gate insulating film GI together with the gate electrode GATE of the driving transistor DRT at a position different from a formation position of the driving transistor DRT.

A first interlayer insulating film ILD1 may be disposed while at least partially covering the gate electrode GATE and the gate material layer GM. A metal pattern TM may be disposed on the first interlayer insulating film ILD1. The metal pattern TM may be disposed at a position different from the formation position of the driving transistor DRT.

A second interlayer insulating film ILD2 may be disposed while at least partially covering the metal pattern TM on the first interlayer insulating film ILD1.

Two first source-drain electrode patterns SD1 may be disposed on the second interlayer insulating film ILD2. One of the two first source-drain electrode patterns SD1 is a source node of the driving transistor DRT, and the other is a drain node of the driving transistor DRT.

The two first source-drain electrode patterns SD1 may be electrically connected to one side and the other side of the active layer ACT through contact holes of the second interlayer insulating film ILD2, the first interlayer insulating film ILD1, and the gate insulating film GI, respectively.

Meanwhile, the second interlayer insulating film ILD2 may include a 2-1 interlayer insulating film ILD2-1 and a 2-2 interlayer insulating film ILD2-2. The 2-1 interlayer insulating film ILD2-1 may be located while covering the metal pattern TM. The 2-2 interlayer insulating film ILD2-2 may be located on the 2-1 interlayer insulating film ILD2-1.

A portion overlapping the gate electrode GATE in the active layer ACT is a channel region. One of the two first source-drain electrode patterns SD1 may be electrically connected to one side of the channel region in the active layer ACT, and the other of the two first source-drain electrode patterns SD1 may be electrically connected to the other side of the channel region in the active layer ACT.

A passivation layer PAS0 is disposed while covering the two first source-drain electrode patterns SD1. A planarization layer PLN may be disposed on the passivation layer PAS0.

The planarization layer PLN may include a first planarization layer PLN1 and a second planarization layer PLN2. The planarization layer PLN may be formed of an organic insulating material such as an acrylic resin, without being limited thereto.

The first planarization layer PLN1 may be disposed on the passivation layer PAS0.

A second source-drain electrode pattern SD2 may be disposed on the first planarization layer PLN1. The second source-drain electrode pattern SD2 may be electrically connected to one of the two first source-drain electrode patterns SD1 through a contact hole of the first planarization layer PLN1.

The second planarization layer PLN2 may be disposed while at least partially covering the second source-drain electrode pattern SD2. The light emitting element ED may be disposed on the second planarization layer PLN2.

The light emitting element ED may include an anode electrode AE, a light emitting layer EL, and a cathode electrode CE.

The anode electrode AE may be disposed on the second planarization layer PLN2. The anode electrode AE may be electrically connected to the second source-drain electrode pattern SD2 through a contact hole of the second planarization layer PLN2.

A bank BANK may be disposed while covering at least a part of the anode electrode AE. A part of the bank BANK corresponding to an emission area EA of the subpixel SP may be opened or exposed.

A part of the anode electrode AE may be exposed through an opening (opened part) of the bank BANK.

The light emitting layer EL may be disposed on a side surface of the bank BANK and in the opening (opened part) of the bank BANK. All or part of the light emitting layer EL may be disposed between adjacent banks BANK. The light emitting layer EL may include an organic film.

In the opening of the bank BANK, the light emitting layer EL may contact the anode electrode AE. The cathode electrode CE may be disposed on the light emitting layer EL.

An encapsulation layer ENCAP may be disposed on the light emitting element ED.

The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic film. Among the first encapsulation layer PAS1, the second encapsulation layer PCL, and the third encapsulation layer PAS2, the second encapsulation layer PCL may be the thickest. Accordingly, the second encapsulation layer PCL may serve as a planarization layer.

The first encapsulation layer PAS1 is also referred to as a first inorganic encapsulation layer, the second encapsulation layer PCL is also referred to as an organic encapsulation layer, and the third encapsulation layer PAS2 is also referred to as a second inorganic encapsulation layer.

The first encapsulation layer PAS1 may be disposed on the cathode electrode CE and may be disposed closest to the light emitting element ED. The first encapsulation layer PAS1 may be formed of an inorganic insulating material capable of low-temperature deposition. For example, the first encapsulation layer PAS1 may be made of silicon nitride (SiNx), silicon oxide (SiOx), silicon oxynitride (SiON), or aluminum oxide (Al₂O₃), without being limited thereto. Since the first encapsulation layer PAS1 is deposited in a low-temperature atmosphere, the first encapsulation layer PAS1 may prevent the light emitting layer EL containing an organic material vulnerable to a high temperature atmosphere from being damaged during a deposition process.

The second encapsulation layer PCL may be formed with a smaller area than the first encapsulation layer PAS1. In this case, the second encapsulation layer PCL may be formed to expose both ends of the first encapsulation layer PAS1. The second encapsulation layer PCL serves as a buffer to relieve stress between respective layers due to bending of the display device 100, and may also serve to strengthen planarization performance.

For example, the second encapsulation layer PCL may include acrylic resin, epoxy resin, polyimide, polyethylene, or silicon oxycarbon (SiOC), and may be formed of an organic insulating material. For example, the second encapsulation layer PCL may be formed through an inkjet method. However, embodiments of the invention are not limited thereto.

The third encapsulation layer PAS2 may be formed on the second encapsulation layer PCL to at least partially cover the upper surfaces and side surfaces of the second encapsulation layer PCL and the first encapsulation layer PAS1, respectively. The third encapsulation layer PAS2 may minimize or block permeation of external moisture or oxygen into the first encapsulation layer PAS1 and the second encapsulation layer PCL.

For example, the third encapsulation layer PAS2 may be formed of an inorganic insulating material such as silicon nitride (SiNx), silicon oxide (SiOx), silicon oxynitride (SiON), or aluminum oxide (Al₂O₃), without being limited thereto.

Meanwhile, in the display device 100 according to an embodiment of the invention, a touch sensor TS for detecting a touch of a user's finger or a pen may be formed on the encapsulation layer ENCAP.

If the touch sensor TS is of a type embedded in the display panel 110, the touch sensor TS may be disposed on the encapsulation layer ENCAP. The structure of the touch sensor will be described in detail as follows.

A touch buffer film T-BUF may be disposed on the encapsulation layer ENCAP.

The touch sensor TS may be disposed on the touch buffer film T-BUF.

The touch sensor TS may include a touch sensor metal TSM and a bridge metal BRG located on different layers.

The touch sensor metal TSM and the bridge metal BRG may have a triple structure of Ti/Al/Ti.

A touch interlayer insulating film T-ILD may be disposed between the touch sensor metal TSM and the bridge metal BRG.

The touch interlayer insulating film T-ILD may be formed of an inorganic material such as silicon nitride (SiNx) or silicon oxide (SiOx). In this case, in order to improve touch performance, the touch interlayer insulating film T-ILD may be formed of an inorganic material of silicon oxide (SiOx). However, embodiments of the invention are not limited thereto.

For example, the touch sensor TS may include a first touch sensor metal, a second touch sensor metal, and a third touch sensor metal disposed adjacent to each other.

If the third touch sensor metal is disposed between the first touch sensor metal and the second touch sensor metal, and the first touch sensor metal and the second touch sensor metal need to be electrically connected to each other, the first touch sensor metal and the second touch sensor metal may be electrically connected to each other through the bridge metal BRG on another layer.

The bridge metal BRG may be insulated from the third touch sensor metal by the touch interlayer insulating film T-ILD.

When forming the touch sensor TS on the display panel 110, a chemical solution (e.g., developer or etchant, etc.) used in a process or moisture from the outside may be generated.

By disposing the touch sensor TS on the touch buffer film T-BUF, penetration of the chemical solution or moisture into the light emitting layer EL containing the organic material during the manufacturing process of the touch sensor TS may be prevented. Accordingly, the touch buffer film T-BUF may prevent damage to the light emitting layer EL vulnerable to the chemical solution or moisture.

The touch buffer film T-BUF may be formed of an organic insulating material capable of being formed at a low temperature equal to or lower than a predetermined temperature (e.g., 100 degrees Celsius) and has a low dielectric constant in order to prevent damage to the light emitting layer EL containing an organic material vulnerable to high temperature. For example, the touch buffer film T-BUF may be formed of an acrylic-based, epoxy-based, or siloxane-based material, without being limited thereto.

As the display device 100 bends or is folded, the encapsulation layer ENCAP may be damaged, and the touch sensor metal TSM disposed on the touch buffer film T-BUF may be damaged. Even if the display device 100 is bent, the touch buffer film TBUF, which is formed of an organic insulating material and has planarization performance, may prevent the encapsulation layer ENCAP from being damaged or the touch sensor metal TSM or the bridge metal BRG from being damaged.

A protective layer PAC may be disposed while at least partially covering the touch sensor TS. The protective layer PAC may be an organic insulating film.

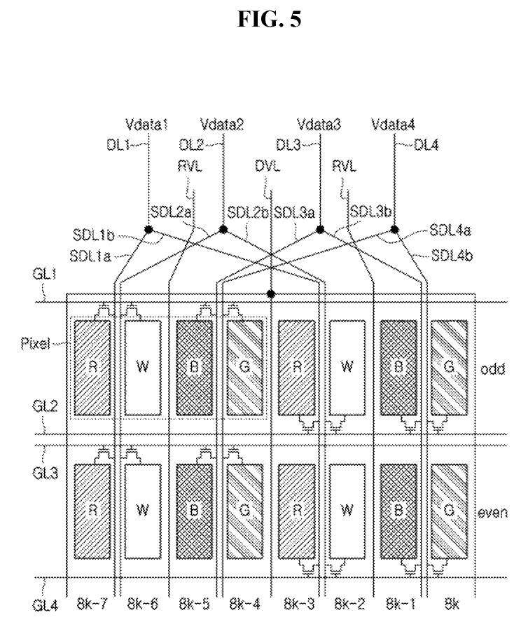

FIG. 5 illustrates an example of a subpixel arrangement of a double rate driving structure in a display device according to an embodiment of the invention.

Referring to FIG. 5, in the display device 100 according to an embodiment of the invention, each pixel may include a red subpixel R emitting red light, a green subpixel G emitting green light, a white subpixel W emitting white light, and a blue subpixel B emitting blue light. Here, a pixel structure emitting light of four colors is illustrated as an example, but one pixel may be composed of any of three subpixels emitting red, green, and blue light in other embodiments.

A plurality of subpixels are arranged along the rows and columns on the display panel 110. In this case, a plurality of subpixels arranged along one row may be referred to as a subpixel line.

For example, if four subpixels SP1, SP2, SP3, and SP4 of white, red, green, and blue constitute one pixel in the display panel 110 having a resolution of 2,160 x 3,840, a total of 15,360 data lines DL may be provided by 2,160 subpixel lines and 3,840 data lines DL respectively electrically connected to the four subpixels SP1, SP2, SP3, and SP4 (3,840 x 4 =15,360).

However, if the display panel 110 is formed in a double rate driving (DRD) structure, two subpixels located in the same subpixel line may be arranged to share one data line. In this case, the subpixels sharing one data line may be left and right subpixels closest to the data line, or may be subpixels of the same color adjacent to the data line.

Here, a case where subpixels of the same color share one data line based on adjacent pixels is illustrated as an example.

For example, one pixel may include four subpixels R, W, B, and G. Here, the first subpixel R may be a red subpixel, the second subpixel W may be a white subpixel, the third subpixel B may be a blue subpixel, and the fourth subpixel G may be a green subpixel. However, embodiments of the invention are not limited thereto, and the plurality of subpixels may be changed to various colors (e.g., Magenta, Yellow, Cyan).

A plurality of subpixels (e.g., R, W, B, and G) of the same color may be disposed in the same column. More particularly, a plurality of first subpixels R may be disposed in the same column, a plurality of second subpixels W may be disposed in the same column, a plurality of third subpixels B may be disposed in the same column, and a plurality of fourth subpixels G may be disposed in the same column.

For example, the plurality of first subpixels R may be disposed in an (8k-7)-th column and an (8k-3)-th column, the plurality of second subpixels W may be disposed in an (8k-6)-th column and an (8k-2)-th column, the plurality of third subpixels B may be disposed in an (8k-5)-th column and an (8k-1)-th column, and the plurality of fourth subpixels G may be disposed in an (8k-4)-th column and an 8k-th column. Here, k is a natural number of 1 or more.

More particularly, the first subpixel R, the second subpixel W, the third subpixel B, and the fourth subpixel G may be sequentially repeated based on odd-numbered rows or one even-numbered row.

Each of the plurality of data lines DL1, DL2, DL3, and DL4 may branch into a plurality of sub-data lines SDL1a, SDL1b, SDL2a, SDL2b, SDL3a, SDL3b, SDL4a, and SDL4b. Specifically, the first data line DL1 may branch into two first sub-data lines SDL1a and SDL1b, the second data line DL2 may branch into two second sub-data lines SDL2a and SDL2b, the third data line DL3 may branch into two third sub-data lines SDL3a and SDL3b, and the fourth data line DL4 may branch into two fourth sub-data lines SDL4a and SDL4b.

The first sub-data lines SDL1a and SDL1-b may include a 1a-th sub-data line SDL1a and a 1b-th sub-data line SDL1b, the second sub-data lines SDL2a and SDL2b may include a 2a-th sub-data line SDL2a and a 2b-th sub-data line SDL2b, the third sub-data lines SDL3a and SDL3b may include a 3a-th sub-data line SDL3a and a 3b-th sub-data line SDL3b, and the fourth sub-data lines SDL4a and SDL4b may include a 4a-th sub-data line SDL4a and a 4b-th sub-data line SDL4b.

The two first sub-data lines SDL1a and SDL1b extend along side surfaces of two first subpixels R adjacent in the row direction, and may be respectively electrically connected to different first subpixels R.

Specifically, the 1a-th sub-data line SDL1a may be disposed between the plurality of first subpixels R disposed in the (8k-7)-th column and the plurality of second subpixels W disposed in the (8k-6)-th column, and electrically connected to the plurality of first subpixels R disposed in the (8k-7)-th column. In addition, the 1b-th sub-data line SDL1b may be disposed between the plurality of first subpixels R disposed in the (8k-3)-th column and the plurality of second subpixels W disposed in the (8k-2)-th column, and electrically connected to the plurality of first subpixels R disposed in the (8k-3)-th column.

The two second sub-data lines SDL2a and SDL2b extend along side surfaces of two second subpixels W adjacent in the row direction, and may be respectively electrically connected to the second subpixels W.

Specifically, the 2a-th sub-data line SDL2a may be disposed between the plurality of first subpixels R disposed in the (8k-7)-th column and the plurality of second subpixels W disposed in the (8k-6)-th column, and electrically connected to the plurality of second subpixels W disposed in the (8k-6)-th column. In addition, the 2b-th sub-data line SDL2b may be disposed between the plurality of first subpixels R disposed in the (8k-3)-th column and the plurality of second subpixels W disposed in the (8k-2)-th column, and electrically connected to the plurality of second subpixels W disposed in the (8k-2)-th column.

The two third sub-data lines SDL3a and SDL3b extend along side surfaces of two third subpixels B adjacent in the row direction, and may be respectively electrically connected to the third subpixels B.

Specifically, the 3a-th sub-data line SDL3-a may be disposed between the plurality of third subpixels B disposed in the (8k-5)-th column and the plurality of fourth subpixels G disposed in the (8k-4)-th column, and electrically connected to the plurality of third subpixels B disposed in the (8k-5)-th column. In addition, the 3b-th sub-data line SDL3b may be disposed between the plurality of third subpixels B disposed in the (8k-1)-th column and the plurality of fourth subpixels G disposed in the 8k-th column, and electrically connected to the plurality of third subpixels B disposed in the (8k-1)-th column.

The two fourth sub-data lines SDL4a and SDL4b extend along side surfaces of two fourth subpixels G adjacent in the row direction, and may be respectively electrically connected to the fourth subpixels G.

Specifically, the 4a-th sub-data line SDL4a may be disposed between the plurality of third subpixels B disposed in the (8k-5)-th column and the plurality of fourth subpixels G disposed in the (8k-4)-th column, and electrically connected to the plurality of fourth subpixels G disposed in the (8k-4)-th column. In addition, the 4b-th sub-data line SDL4b may be disposed between the plurality of third subpixels B disposed in the (8k-1)-th column and the plurality of fourth subpixels G disposed in the 8k-th column, and electrically connected to the plurality of fourth subpixels G disposed in the 8k-th column.

In this case, a first data voltage Vdata1, which is a red data voltage, may be supplied to the first data line DL1, a second data voltage Vdata2, which is a white data voltage, may be supplied to the second data line DL2, a third data voltage Vdata3, which is a blue data voltage, may be supplied to the third data line DL3, and a fourth data voltage Vdata4, which is a green data voltage, may be supplied to the fourth data line DL4.

Since the two first sub-data lines SDL1a and SDL1b branch from the first data line DL1, the first data voltage Vdata1, which is the red data voltage, may also be supplied to the two first sub-data lines SDL1a and SDL1b.

Since the two second sub-data lines SDL2a and SDL2b branch from the second data line DL2, the second data voltage Vdata2, which is the white data voltage, may also be supplied to the two second sub-data lines SDL2a and SDL2b.

Since the two third sub-data lines SDL3a and SDL3b branch from the third data line DL3, the third data voltage Vdata3, which is the blue data voltage, may also be supplied to the two third sub-data lines SDL3a and SDL3b.

Since the two fourth sub-data lines SDL4a and SDL4b branch from the fourth data line DL4, the fourth data voltage, Vdata4 which is the green data voltage, may also be supplied to the two fourth sub-data lines SDL4a and SDL4b.

In this case, in order to drive the plurality of subpixels R, G, B, and W corresponding to one subpixel line, two gate lines may be disposed on both sides of each subpixel line.

For example, a first gate line GL1 and a second gate line GL2 may be disposed on both sides of a plurality of subpixels R, G, B, and W in an odd-numbered row, and a third gate line GL3 and a fourth gate line GL4 may be disposed on both sides of a plurality of subpixels R, G, B, and W in an even-numbered row. In this case, the second gate line GL2 and the third gate line GL3 may be disposed between the plurality of subpixels R, G, B, and W in the odd-numbered row and the plurality of subpixels R, G, B, and W in the even-numbered row.

In this case, two pixels adjacent in the row direction may be electrically connected to different gate lines.

For example, subpixels R, W, B, and G disposed in the (8k-7)-th to (8k-4)-th columns of the odd-numbered row may be electrically connected to the first gate line GL1, and subpixels R, W, B, and G disposed in the (8k-3)-th to 8k-th columns of the odd-numbered row may be electrically connected to the second gate line GL2. In addition, subpixels R, W, B, and G disposed in the (8k-7)-th to (8k-4)-th columns of the even-numbered row may be electrically connected to the third gate line GL3, and subpixels R, W, B, and G disposed in the (8k-3)-th to 8k-th columns of the even-numbered row may be electrically connected to the fourth gate line GL4.

In addition, each of the plurality of reference voltage lines RVL may be disposed inside one pixel, and each of the driving voltage lines DVL to which the plurality of pixel high-potential voltages EVDD are supplied may be disposed between a plurality of adjacent pixels.

Specifically, the plurality of reference voltage lines RVL may be disposed between the plurality of second subpixels W disposed in the (8k-6)-th column and the plurality of third subpixels B disposed in the (8k-5)-th column, and may be disposed between the plurality of second subpixels W disposed in the (8k-2)-th column and the plurality of third subpixels B disposed in the (8k-1)-th column.

In addition, the plurality of driving voltage lines DVL may be disposed between the plurality of fourth subpixels G disposed in the (8k-4)-th column and the plurality of first subpixels R disposed in the (8k-3)-th column, disposed outside the plurality of first subpixels R disposed in the (8k-7)-th column, and disposed outside the plurality of fourth subpixels G disposed in the 8k-th column.

As described above, in the case of the double rate driving (DRD) structure, since one data line is disposed for every two subpixels, if the number of subpixels in the column direction is m, the number of data lines DL may be reduced to m/2.

However, in the double rate driving, since the number of gate lines doubles, one horizontal period of the scan signal supplied through the gate line becomes short, which makes it difficult to secure the charging time of the data voltage.

The display device 100 of the invention sets 3 x 2 pixels as one pixel group, and controls one pixel group with three gate lines and two pixel data lines, thereby providing an improved structure capable of securing the charging time of the data voltage while reducing the number of data lines.

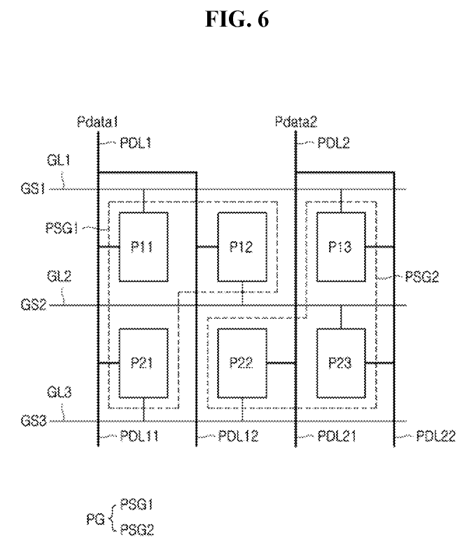

FIG. 6 illustrates an example of a connection relationship between gate lines and data lines for each pixel group in a display device according to an embodiment of the invention.

Referring to FIG. 6, the display device 100 according to an embodiment of the invention may set 3 x 2 pixels as one pixel group PG, and control one pixel group PG with three gate lines GL1, GL2, and GL3 and two pixel data lines PDL1 and PDL2.

Here, it is illustrated one pixel group PG consisting of an 11th pixel P11, a 12th pixel P12, and a 13th pixel P13 disposed in a pixel line of a first row, and a 21st pixel P21, a 22nd pixel P22, and a 23rd pixel P23 disposed in a pixel line of a second row.

Each of the pixels P11 to P13 and P21 to P23 may be composed of three subpixels of red (R), green (G), and blue (B), or may be composed of four subpixels of red (R), green (G), blue (B), and white (W).

In addition, the pixel data lines PDL1 and PDL2 represent data lines supplying pixel data voltages Pdata1 and Pdata2 to each pixel in units of pixels. Accordingly, the pixel data lines PDL1 and PDL2 may include three subpixel data lines supplying subpixel data voltages to three subpixels of red (R), green (G), and blue (B), or may include four subpixel data lines supplying subpixel data voltages to four subpixels of red (R), green (G), blue (B), and white (W). Here, the pixel data voltages Pdata1 and Pdata2 may be considered as terms collectively referring to subpixel data voltages supplied to subpixels constituting each pixel.

The pixel group PG including the 3 x 2 pixels P11 to P13 and P21 to P23 may include a first pixel sub-group PSG1 to which a first pixel data voltage Pdata1 is supplied through a first pixel data line PDL1, and a second pixel sub-group PSG2 to which a second pixel data voltage Pdata2 is supplied through a second pixel data line PDL2. The first pixel sub-group PSG1 may include the 11th pixel P11, the 12th pixel P12, and the 21st pixel P21, and the second pixel sub-group PSG2 may include the 13th pixel P13, the 22nd pixel P22, and the 23rd pixel P23. That is, the first pixel sub-group PSG1 and the second pixel sub-group PSG2 may have a similar arrangement.

The first pixel data line PDL1 may branch into an 11th pixel data line PDL11 and a 12th pixel data line PDL12. The 11th pixel data line PDL11 may supply the first pixel data voltage Pdata1 to the 11th pixel P11 and the 21st pixel P21, and the 12th pixel data line PDL12 may supply the first pixel data voltage Pdata1 to the 12th pixel P12.

The second pixel data line PDL2 may branch into a 21st pixel data line PDL21 and a 22nd pixel data line PDL22. The 21st pixel data line PDL21 may supply the second pixel data voltage Pdata2 to the 22nd pixel P22, and the 22nd pixel data line PDL22 may supply the second pixel data voltage Pdata2 to the 13th pixel P13 and the 23rd pixel P23.

The three gate lines GL1, GL2, and GL3 may be arranged along the pixel line of the row direction.

As described above, in the case that 3 x 2 pixels are set as one pixel group PG and one pixel group PG is controlled by three gate lines GL1, GL2, and GL3 and two pixel data lines PDL1 and PDL2, if the number of subpixels in the row direction is m, the number of data lines may be reduced to 2m/3.

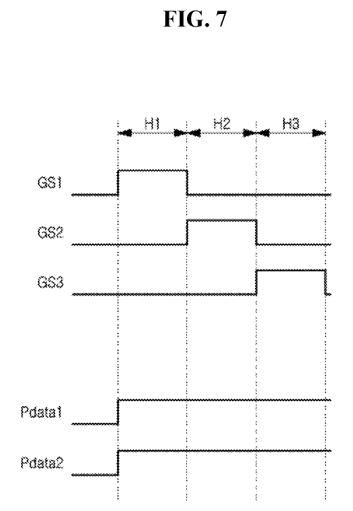

FIG. 7 illustrates an example of signal timing for gate signals and data voltages of a display device according to an embodiment of the invention.

Referring to FIGS. 6 and 7, in the display device 100 according to an embodiment of the invention, a first gate signal GS1 may be supplied through the first gate line GL1, a second gate signal GS2 may be supplied through the second gate line GL2, and a third gate signal GS3 may be supplied through the third gate line GL3.

In addition, the first pixel data voltage Pdata1 may be supplied through the first pixel data line PDL1, and the second pixel data voltage Pdata2 may be supplied through the second pixel data line PDL2.

In a first horizontal period H1, the first gate signal GS1 may be supplied as a gate high voltage which is a turn-on level, and the second gate signal GS2 and the third gate signal GS3 may be supplied as a gate low voltage which is a turn-off level. In addition, in the first horizontal period H1, the first pixel data voltage Pdata1 and the second pixel data voltage Pdata2 may be supplied at a level for implementing a predetermined gray scale.

Therefore, during the first horizontal period H1, scan transistors electrically connected to the 11th pixel P11 and the 13th pixel P13 electrically connected to the first gate line GL1 may be all turned on. As a result, the 11th pixel P11 may emit light of a color determined by the first pixel data voltage Pdata1, and the 13th pixel P13 may emit light of a color determined by the second pixel data voltage Pdata2.

In a second horizontal period H2, the second gate signal GS2 may be supplied as a gate high voltage which is a turn-on level, and the first gate signal GS1 and the third gate signal GS3 may be supplied as a gate low voltage which is a turn-off level. In addition, in the second horizontal period H2, the first pixel data voltage Pdata1 and the second pixel data voltage Pdata2 may be supplied at a level for implementing a predetermined gray scale.

Therefore, during the second horizontal period H2, scan transistors electrically connected to the 12th pixel P12 and the 23rd pixel P23 electrically connected to the second gate line GL2 may be all turned on. As a result, the 12th pixel P12 may emit light of a color determined by the first pixel data voltage Pdata1, and the 23rd pixel P23 may emit light of a color determined by the second pixel data voltage Pdata2.

In a third horizontal period H3, the third gate signal GS3 may be supplied as a gate high voltage which is a turn-on level, and the first gate signal GS1 and the second gate signal GS2 may be supplied as a gate low voltage which is a turn-off level. In addition, in the third horizontal period H3, the first pixel data voltage Pdata1 and the second pixel data voltage Pdata2 may be supplied at a level for implementing a predetermined gray scale.

Therefore, during the third horizontal period H3, scan transistors electrically connected to the 21st pixel P21 and the 22nd pixel P22 electrically connected to the third gate line GL3 may be all turned on. As a result, the 21st pixel P21 emits light of a color determined by the first pixel data voltage Pdata1, and the 22nd pixel P22 emits light of a color determined by the second pixel data voltage Pdata2.

As described above, the display device 100 of the invention controls one pixel group PG composed of 3 x 2 pixels with three gate lines GL1, GL2, and GL3 and two pixel data lines PDL1 and PDL2, thereby reducing the number of gate lines and data lines and securing the charging time of the data voltage.

In addition, since two pixels share one pixel data line PDL in the display device 100 of the invention, the density of the pixel data lines PDL may increase. Therefore, in order to secure a design margin for signal lines of a pixel circuit for driving pixels, pixel circuit areas may be alternately arranged so as not to overlap with each other.

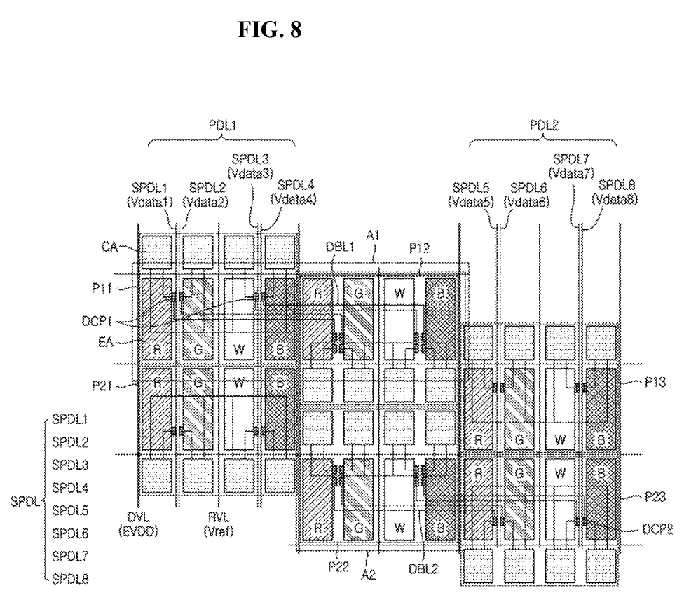

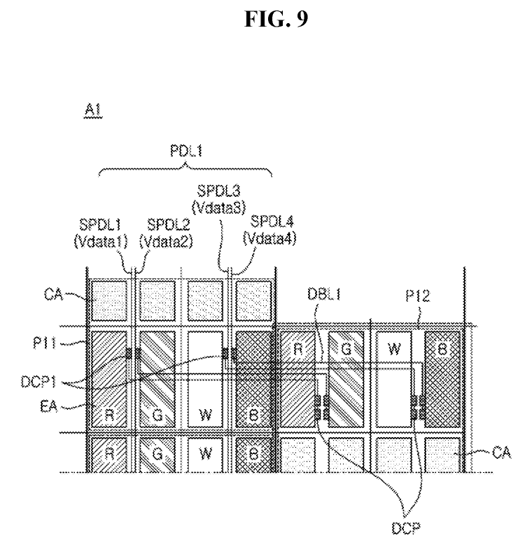

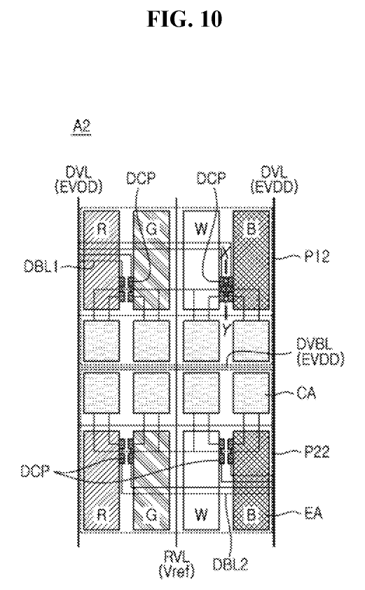

FIG. 8 specifically illustrates a pixel group structure of a display device according to an embodiment of the invention, FIG. 9 is an enlarged view of area A1 of FIG. 8, and FIG. 10 is an enlarged view of area A2 of FIG. 8.

Referring to FIGS. 8 and 9, in the display device 100 according to an embodiment of the invention, each of the pixels P11 to P13 and P21 to P23 constituting the pixel group PG of 3 x 2 arrangement may each include an emission area EA emitting light and a circuit area CA controlling the operation of the pixel.

In this case, the circuit areas CA of the respective pixels P11 to P13 and P21 to P23 disposed in one pixel group may be arranged so as not to overlap in the first direction (e.g., horizontal direction). As a result, since the gate lines GL1, GL2, and GL3 supplying gate signals to the circuit area CA may be spaced apart at regular intervals, overlap noise due to gate signals between adjacent gate lines may be reduced.

The circuit area CA may be disposed above or below the emission area EA. Therefore, adjacent pixels in the second direction (e.g., vertical direction) may have their emission areas EA arranged adjacent to each other, or their circuit areas CA arranged adjacent to each other.

For example, the 11th pixel P11 and the 21st pixel P21 may be arranged such that their emission areas EA are adjacent to each other, and the 12th pixel P12 and the 22nd pixel P22 may be arranged such that their circuit areas CA are adjacent to each other. In addition, the 13th pixel P13 and the 23rd pixel P23 may be arranged such that their emission areas EA are adjacent to each other.

In this case, if the 11th pixel P11 and the 21st pixel P21 disposed on the left side of the pixel group PG are composed of four subpixels of red (R), green (G), white (W), and blue (B), four subpixel data lines SPDL1 to SPDL4 may extend in the second direction along the inside of the pixels P11 and P21. In this case, the subpixel data lines SPDL1 to SPDL4 may be disposed along spaces between adjacent subpixels R, G, W, and B.

For example, the first subpixel data line SPDL1 to which the first data voltage Vdata1 is supplied and the second subpixel data line SPDL2 to which the second data voltage Vdata2 is supplied may be disposed in a space between the red subpixel R and the green subpixel G. In addition, the third subpixel data line SPDL3 to which the third data voltage Vdata3 is supplied and the fourth subpixel data line SPDL4 to which the fourth data voltage Vdata4 is supplied may be disposed in a space between the white subpixel W and the blue subpixel B.

In addition, four subpixel data lines SPDL6 to SPDL8 may extend in the second direction along spaces between adjacent subpixels R, G, W, and B inside the 13th pixel P13 and the 23rd pixel P23 located on the right side of the pixel group PG.

For example, a fifth subpixel data line SPDL5 to which a fifth data voltage Vdata5 is supplied and a sixth subpixel data line SPDL6 to which a sixth data voltage Vdata6 is supplied may be disposed in a space between the red subpixel R and the green subpixel G. In addition, a seventh subpixel data line SPDL7 to which a seventh data voltage Vdata7 is supplied and an eighth subpixel data line SPDL8 to which an eighth data voltage Vdata8 is supplied may be disposed in a space between the white subpixel W and the blue subpixel B.

Meanwhile, the 12th pixel P12 and the 22nd pixel P22 disposed at the center of the pixel group PG may receive data voltages through a first data bridge line DBL1 branching from the subpixel data lines SPDL1 to SPDL4 on the left side and a second data bridge line DBL2 branching from the subpixel data lines SPDL5 to SPDL8 on the right side.

For example, the first to fourth subpixel data lines SPDL1 to SPDL4 may branch into the first data bridge line DBL1 at a first data line contact point DCP1 formed in the emission area EA of the 11th pixel P11. Therefore, the first data bridge line DBL1 may extend along the emission area EA of the 11th pixel P11 and be electrically connected to a corresponding subpixel of the 12th pixel P12. In this case, a data line contact point may be also formed in the emission area EA of the 12th pixel P12, so that the first data bridge line DBL1 may be electrically connected to the emission area EA and the circuit area CA of the 12th pixel P12.

In addition, the fifth to eighth subpixel data lines SPDL5 to SPDL8 may branch into the second data bridge line DBL2 at a second data line contact point DCP2 formed in the emission area EA of the 23rd pixel P23. Therefore, the second data bridge line DBL2 may extend along the emission area EA of the 23rd pixel P23 and be electrically connected to a corresponding subpixel of the 22nd pixel P22. In this case, a data line contact point may be also formed in the emission area EA of the 22nd pixel P22, so that the second data bridge line DBL2 may be electrically connected to the emission area EA and the circuit area CA of the 22nd pixel P22.

Therefore, the display device 100 of the invention supplies the data voltage to the central pixels P12 and P22 through the data bridge lines DBL1 and DBL2 branching from the pixel data lines PDL1 and PDL2 on both sides in the pixel group PG along the emission area EA, thereby reducing noise capacitance due to overlap of signal lines.

Here, a case where the circuit areas of the pixel group PG are arranged so as not to overlap in the first direction is illustrated as an example to secure a design margin for the signal lines of the pixel circuit, but the emission areas EA of respective pixels may be arranged side by side in the first direction, or the circuit areas CA of respective pixels may be arranged side by side in the first direction.

In addition, in the case of adjacent pixels (e.g., the 11th pixel P11 and the 12th pixel P12), a flip structure in which the circuit area CA of the 11th pixel P11 is disposed above the emission area EA and the circuit area CA of the 12th pixel P12 is disposed below the emission area EA is illustrated as an example.

However, the display device 100 of the invention may be formed in a flip structure in which the position of the circuit area CA is alternated in units of at least one subpixel within one pixel.

In addition, in the case of pixels in which circuit areas CA are disposed adjacent to each other (e.g., the 12th pixel P12 and the 22nd pixel P22), a driving voltage bridge line DVBL may be arranged to share a driving voltage line DVL supplying the pixel high-potential voltage EVDD along a central portion of the circuit areas CA.

Referring to FIG. 10, in the display device 100 of the invention, pixels P12 and P22 located in the center among the pixel group PG of 3 x 2 arrangement may have circuit areas CA arranged adjacent to each other.

If the circuit areas CA are arranged adjacent to each other, since there is room in the space between the circuit areas CA, the driving voltage bridge line DVBL branching from the driving voltage line DVL supplying the pixel high-potential voltage EVDD may be additionally disposed. Therefore, the pixel high-potential voltage EVDD may be effectively supplied to each circuit area CA.

In the display device 100 of the invention, the subpixel data line SPDL and the data bridge line DBL are electrically connected using a light shield layer at the data line contact point DCP, thereby reducing the number of data lines for the pixels P12 and P22 in the central area.

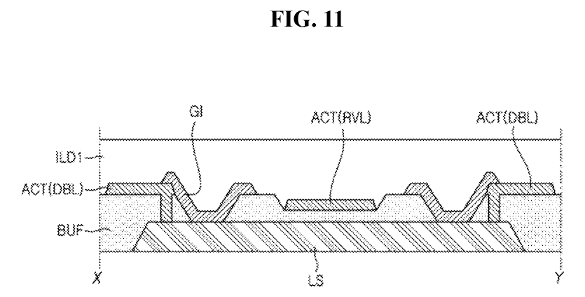

FIG. 11 illustrates an example of a cross-section obtained by cutting the data line contact point in an X-Y direction in FIG. 10.

Referring to FIG. 11, the display device 100 of the invention may electrically connect the subpixel data line SPDL and the data bridge line DBL using a light shield layer at the data line contact point DCP formed in the emission area EA.

A light shield layer LS blocking light may be formed in some areas on the substrate of the display panel. The light shield layer LS may be formed of a metal material, and a buffer layer BUF may be formed on the light shield layer LS. Here, the buffer layer BUF formed on the light shield layer LS may be referred to as an active buffer layer.

An active layer ACT of the driving transistor DRT may be disposed on the buffer layer BUF. In this case, the data bridge line DBL may be formed using the active layer ACT. For example, the data bridge line DBL and the active layer ACT may include the same material. Here, a case where the data bridge line DBL is formed using the active layer ACT on the buffer layer BUF on both sides with respect to the light shield layer LS in the 12th pixel P12 and the 22nd pixel P22 disposed at the center of the pixel group PG is illustrated as an example.

In the case of the 11th pixel P11 and the 21st pixel P21 disposed on the left side of the pixel group PG, or the 13th pixel P13 and the 23rd pixel P23 disposed on the right side, with respect to the light shield layer LS, the data bridge line DBL may be formed on one side and the subpixel data line SPDL may be formed on the other side.

A gate insulating film GI may be disposed in a part of the upper portion of the buffer layer BUF.

A reference voltage line RVL to which a reference voltage Vref is supplied may be disposed at the data line contact point DCP of the 12th pixel P12 and the 22nd pixel P22. The reference voltage line RVL may be formed of the active layer ACT.

In this case, the data bridge line DBL may be electrically connected to the light shield layer LS through a contact hole. Therefore, the data bridge line DBL on one side may be connected to the data bridge line DBL on the other side through the light shield layer LS at the data line contact point DCP.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel including a plurality of pixel groups, each pixel group having a 3 x 2 arrangement in which three pixels are arranged in a first direction and two pixels are arranged in a second direction;
a gate driving circuit configured to supply a gate signal to the display panel through a gate line; and
a data driving circuit configured to supply a pixel data voltage to the display panel through a pixel data line,
wherein the pixel group includes:
a first pixel sub-group to which a first pixel data voltage is configured to be supplied through a first pixel data line extending along the second direction; and
a second pixel sub-group to which a second pixel data voltage is configured to be supplied through a second pixel data line extending along the second direction, and
wherein the pixel group is configured to operate based on three gate signals supplied through three gate lines extending along the first direction.

2. The display device of claim 1, wherein the first pixel sub-group is arranged in a shape similar to a shape of the second pixel sub-group.

3. The display device of claim 2, wherein the first pixel sub-group includes:
an 11th pixel disposed in a first row and a first column;
a 12th pixel disposed in the first row and a second column; and
a 21st pixel disposed in a second row and the first column.

4. The display device of claim 3, wherein the second pixel sub-group includes:
a 13th pixel disposed in the first row and a third column;
a 22nd pixel disposed in the second row and the second column; and
a 23rd pixel disposed in the second row and the third column.

5. The display device of claim 4, wherein the three gate lines include:
a first gate line disposed outside pixels of the first row;
a second gate line disposed between the pixels of the first row and pixels of the second row; and
a third gate line disposed outside the pixels of the second row.

6. The display device of claim 5, wherein the 11th pixel and the 13th pixel operate based on a first gate signal supplied through the first gate line,
wherein the 12th pixel and the 23rd pixel operate based on a second gate signal supplied through the second gate line, and
wherein the 21st pixel and the 22nd pixel operate based on a third gate signal supplied through the third gate line.

7. The display device of claim 6, wherein the 11th pixel and the 21st pixel are supplied with the first pixel data voltage through the first pixel data line,
wherein the 13th pixel and the 23rd pixel are supplied with the second pixel data voltage through the second pixel data line,
wherein the 12th pixel is supplied with the first pixel data voltage through a first data bridge line branching from the first pixel data line, and
wherein the 22nd pixel is supplied with the second pixel data voltage through a second data bridge line branching from the second pixel data line.

8. The display device of claim 7, wherein the first data bridge line branches at a first data line contact point formed adjacent to an emission area of the 11th pixel, and the second data bridge line branches at a second data line contact point formed adjacent to an emission area of the 23rd pixel.

9. The display device of claim 8, further comprising:
a driving transistor including an active layer; and
a lower light shield layer,
wherein each of the first and second data bridge lines includes the same material as the active layer of the driving transistor, and each of the first and second data bridge lines is electrically connected through the lower light shield layer at the first data line contact point or the second data line contact point.

10. The display device of claim 7, wherein each pixel in the pixel group includes an emission area and a circuit area,
wherein pixels within the pixel group are arranged so that the circuit areas do not overlap with each other along the first direction.

11. The display device of claim 10, wherein the 12th pixel and the 22nd pixel are arranged such that respective circuit areas are adjacent to each other in the second direction.

12. The display device of claim 11, further comprising:
a driving voltage line extending along the second direction in a space between adjacent pixels in the first direction and transmitting a pixel high-potential voltage; and
a driving voltage bridge line branching from the driving voltage line in the first direction along a space between a circuit area of the 12th pixel and a circuit area of the 22nd pixel.

13. The display device of claim 1, wherein each pixel in the pixel group includes an emission area and a circuit area, and
wherein the pixel group has a flip structure in which the arrangement of the emission area and the circuit area alternates in units of pixels.

14. The display device of claim 8, wherein each of the first pixel data line and the second pixel data line comprises a plurality of subpixel data lines extending in the second direction along spaces between a part of adjacent sub-pixels in the pixels of the pixel groups, and
wherein the first data line contact point and the second data line contact point are respectively located at positions adjacent to emission area of each subpixel in the spaces.

15. A display panel comprising:
a pixel group having a 3 x 2 arrangement in which three pixels are arranged in a first direction and two pixels are arranged in a second direction;
three gate lines extending along the first direction and supplying gate signals;
a first pixel data line extending along the second direction and supplying a first pixel data voltage to a first pixel sub-group of the pixel group; and
a second pixel data line extending along the second direction and supplying a second pixel data voltage to a second pixel sub-group of the pixel group.

16. The display panel of claim 15, wherein the three gate lines include:
a first gate line disposed outside pixels of a first row;
a second gate line disposed between the pixels of the first row and pixels of a second row; and
a third gate line disposed outside the pixels of the second row.

17. The display panel of claim 15, wherein one of pixels disposed in a center column of the pixel group is supplied with the first pixel data voltage through a first data bridge line branching from the first pixel data line, and the other of the pixels disposed in the center column in the pixel group is supplied with the second pixel data voltage through a second data bridge line branching from the second pixel data line.

18. The display panel of claim 17, wherein the first data bridge line branches at a first data line contact point formed adjacent to an emission area of a pixel disposed in a left column in the pixel group, and
wherein the second data bridge line branches at a second data line contact point formed adjacent to an emission area of a pixel disposed in a right column in the pixel group.

19. The display panel of claim 18, further comprising:
a driving transistor including an active layer; and
a lower light shield layer,
wherein each of the first data bridge line and the second data bridge line includes the same material as the active layer of the driving transistor, and each of the first data bridge line and the second data bridge line is electrically connected through the lower light shield layer at the first data line contact point or the second data line contact point.

20. The display panel of claim 15, wherein each pixel in the pixel group includes an emission area and a circuit area,
wherein the pixel group has a flip structure in which the arrangement of the emission area and the circuit area alternates in units of pixels.
